(19) United States
(12) Patent Application Publication
(10) Pub. No.: US 2020/0306802 A1
(43) Pub. Date: Oct. 1, 2020

(54) SURFACE TREATMENT METHOD AND SURFACE TREATMENT APPARATUS

(71) Applicant: SEKISUI CHEMICAL CO., LTD., Osaka (JP)

(72) Inventors: Hiroaki AlBA, Kyoto-shi, Kyoto (JP); Mamoru HINO, Kyoto-shi, Kyoto (JP); Masato AKAHORI, Kyoto-shi, Kyoto (JP)

(73) Assignee: SEKISUI CHEMICAL CO., LTD., Osaka (JP)

(21) Appl. No.: 16/754,996

(22) PCT Filed: Dec. 17, 2018
(86) PCT No.: PCT/JP2018/046396

§ 371 Date: Apr. 9, 2020

(30) Foreign Application Priority Data
Dec. 18, 2017 (JP) 2017-241512

(51) Int. Cl. B08B 7/04; H01L 21/321; H01L 21/02; H01L 21/67; B08B 5/00; B08B 7/00

(52) U.S. Cl. CPC B08B 7/04; H01L 21/321; B08B 7/0057; H01L 21/67051; B08B 5/00; H01L 21/02068

(57) ABSTRACT

It is an objective of the present invention to suppress or prevent damages to a metal layer when a surface of a substrate having an easily oxidizable metal layer formed therein is dry-processed and subsequently wet-cleaned. In a dry-processing part 10, a reducing gaseous fluid containing a reducing component is brought into contact with an easily oxidizable metal layer 93 on a surface of a workpiece substrate 90 and the reducing gaseous fluid is activated generally concurrently with the contacting. Subsequently, the workpiece substrate 90 is moved on to a wet-cleaning part 20 and cleaned with cleaning liquid 29.

### FIELD OF THE INVENTION

The present invention relates to a method and an apparatus for treating a surface of a workpiece substrate including an easily oxidizable metal layer, and particularly relates to a surface treatment method including dry-processing and wet-cleaning and a surface treatment apparatus therefor.

### BACKGROUND OF THE INVENTION

In a manufacturing process of a semiconductor such as TFT (thin-film transistor), an electrode pattern is formed, for example, by forming a layer of metal such as Cu on a surface of a substrate, cleaning the substrate, then providing a resist and photo-etching the metal layer (refer to Patent Document 1, for example).

Methods for the cleaning include dry-cleaning and wet-cleaning. The cleaning reduces a contact angle and enhances hydrophilic property, making it easier to coat the resist.

### PRIOR ART DOCUMENTS

### Patent Documents

Patent Document 1: Japanese Unexamined Patent Application Publication No. 2001-87719

### SUMMARY OF THE INVENTION

### Problem to be Solved by the Invention

According to the findings of the inventors, scattered or spotted dissolution damages may be formed in a surface of a metal layer when a substrate is dry-cleaned and then wet-cleaned with water in order to enhance a hydrophilic property of the substrate. For the dry-cleaning, an oxidizing process gas containing N₂ and O₂, for example, is activated by an activator such as plasma or excimer UV and brought into contact with the substrate. Particularly, the metal layer made of easily oxidizable metal such as Cu can be easily damaged. When an electrode pattern is formed on a damaged metal layer, a wiring failure may occur.

In view of the above, it is an objective of the present invention to suppress or prevent damages to a metal layer when a surface of a substrate having an easily oxidizable metal layer formed thereon is dry-processed and then wet-cleaned.

### Means for Solving the Problems

To solve the problems mentioned above, the inventors have made intensive studies and considerations.

It is inferred that an oxidizing corrosive component such as nitric acid or the like may be generated by the activation of the oxidizing process gas, and the oxidizing corrosive component may be adhered to or adsorbed by a workpiece substrate. On the other hand, when the workpiece substrate is moved on to a wet-cleaning step, misty water floating in the atmosphere near a wet-cleaning part may adhere to the workpiece substrate. This may result in generation of corrosive aqueous solution such as aqueous solution of nitric acid on a metal layer on a surface of the workpiece substrate. Copper of the metal layer may be dissolved in the aqueous solution. It is considered that this may cause the damages.

The present invention was made based on such considerations. The present invention provides a surface treatment method for treating a surface of a workpiece substrate including an easily oxidizable metal layer, the method including steps of: bringing a reducing gaseous fluid containing a reducing component into contact with the workpiece substrate; activating the reducing gaseous fluid generally concurrently with the contacting; and subsequently cleaning the workpiece substrate with cleaning liquid.

By the surface treatment, a contact angle of the workpiece substrate may be reduced and a hydrophilic property may be enhanced, thereby adhesiveness to a resist or the like can be improved. Furthermore, by making the reducing gaseous fluid contain the reducing component, generation of oxidizing corrosive component during the activation can be avoided. Or even if the oxidizing corrosive component is generated, the oxidizing property or the corrosive property can be reduced by a reducing action of the reducing component. Thereby, generation of corrosive aqueous solution on the surface of the workpiece substrate at the time of wet-cleaning can be prevented or suppressed. As a result, the easily oxidizable metal layer can be prevented or suppressed from being damaged.

The reducing gaseous fluid maybe brought into contact with the workpiece substrate after being activated.

The reducing gaseous fluid maybe activated after being brought into contact with the workpiece substrate.

The reducing gaseous fluid maybe brought into contact with the workpiece substrate and may be activated at the same time.

Preferably, the activation is performed by plasma treatment, corona discharge treatment, ultraviolet irradiation treatment or microwave irradiation treatment.

In the plasma treatment, the reducing gaseous fluid is activated by plasma. Preferably, the activation is performed by generating electric discharge between a pair of electrodes. Preferably, a diluent component also serves as an electric discharge generating gas.

In the corona discharge treatment, the reducing gaseous fluid is activated by corona discharge. In the ultraviolet irradiation treatment, the reducing gaseous fluid is activated by ultraviolet irradiation. In the microwave irradiation treatment, the reducing gaseous fluid is activated by microwave irradiation.

The reducing component is an elementary substance or a compound that has a reducing action. The reducing component may be an elementary substance or a compound that acquires a reducing action by the activation. Such reducing component may be hydrogen (H₂), hydrogen sulfide (H₂S), hydrogen peroxide (H₂O₂), carbon monoxide (CO) or hydrogen-oxygen-containing compound. The reducing gaseous fluid may contain a plurality of species of reducing components. The hydrogen-oxygen-containing compound is a compound containing a hydrogen atom (H) and an oxygen atom (O), which may include a lower alcohol such as ethanol, methanol and isopropanol and water.

The reducing gaseous fluid may be a mixed fluid of the reducing component and a diluent gas. The diluent gas may be an inert gas such as nitrogen (N₂) and rare gas, and preferably nitrogen in light of economic efficiency, etc. For example, content percentage of the reducing component CO in the reducing gaseous fluid may preferably be around 100 ppm to 5 percent (volume content percentage).

The reducing gaseous fluid may be in a state of mist as well as in a state of gas.

After the reducing gaseous fluid in a gaseous state (gas phase) is brought into contact with the workpiece substrate, the reducing gaseous fluid may be condensed on the workpiece substrate and may be in a liquid phase. A condensation point of the reducing gaseous fluid may be lower than a temperature of the workpiece substrate.

The reducing gaseous fluid may contain a plurality of species of reducing components. For example, the reducing gaseous fluid may be a mixture of a lower alcohol such as ethanol and water.

The reducing gaseous fluid may be fixable to the workpiece substrate by the contacting with the workpiece substrate; and the oxidizing gaseous fluid may be activated and brought into contact with the workpiece substrate on which the reducing gaseous fluid is fixed. The reducing gaseous fluid may be fixed by condensation, adhesion, adsorption or the like. The oxidizing gaseous fluid may be a mixed gas of nitrogen and oxygen. CDA or the like. The activated oxidizing gaseous fluid is brought into contact with the workpiece substrate, and thereby the reducing gaseous fluid on the workpiece substrate is indirectly provided with activation energy. Thereby, the metal layer can be surely prevented from being corroded, and a cleaning effect can be enhanced.

After the reducing gaseous fluid is activated and brought into contact with the workpiece substrate, the oxidizing gaseous fluid may be activated and brought into contact with the workpiece substrate. Reversely, after the oxidizing gaseous fluid is activated and brought into contact with the workpiece substrate, the reducing gaseous fluid may be activated and brought into contact with the workpiece substrate.

Furthermore, the reducing gaseous fluid may contain an oxidizing component. The oxidizing component is required to have an oxidizing property or to contain an oxygen atom. The oxidizing component may be CDA (clean dry air), oxygen (O₂), ozone (O₃), nitrogen monoxide (N₂O) or the like, and may preferably be CDA or oxygen (O₂).

Preferably, the cleaning liquid in the wet-cleaning step is water. The cleaning liquid may be alcohol.

The present invention provides a surface treatment apparatus for treating a surface of a workpiece substrate including an easily oxidizable metal layer, the apparatus including:

a dry-processing part, wherein a reducing gaseous fluid containing a reducing component is brought into contact with the workpiece substrate and the reducing gaseous fluid is activated generally concurrently with the contacting; and

a wet-cleaning part, wherein the workpiece substrate after the contacting and providing is cleaned with cleaning liquid.

Preferably, the dry-processing part includes a pair of electrodes and the activation is performed by generating electric discharge between the electrodes. Thereby, yield can be improved. Preferably, a type of discharge is a dielectric-barrier discharge under a near atmospheric pressure.

The near atmospheric pressure refers to a pressure in a region of 1.013×10⁴ to 50.663×10⁴ Pa. Considering ease of pressure adjustment and simplicity of apparatus configuration, the near atmospheric pressure is preferably 1.333×10⁴ to 10.664×10⁴ Pa, and more preferably, 9.331×10⁴ to 10.397×10⁴ Pa.

Besides a plasma generator, the activator may be a corona discharger wherein the gas is activated by corona discharge, an ultraviolet irradiator wherein the gas is activated by ultraviolet irradiation, and a microwave irradiator wherein the gas is activated by microwave irradiation.

Preferably, the easily oxidizable metal layer contains at least one kind of metal selected from a group of copper, aluminum, iron and zinc. The easily oxidizable metal includes a metal having an ionization tendency equal to or higher than that of copper (Cu).

Preferably, the easily oxidizable metal is highly conductive in addition to highly oxidizable.

More preferably, the easily oxidizable metal layer is composed of copper (Cu).

### Advantageous Effects of the Invention

According to the present invention, when a surface of a substrate having an easily oxidizable metal layer formed thereon is wet-cleaned after being dry-processed, the metal layer can be suppressed or prevented from being damaged.

### BRIEF DESCRIPTION OF THE DRAWINGS

FIG. 1 is an explanatory diagram showing a schematic configuration of a surface treatment apparatus according to one embodiment of the present invention.

FIGS. 2 (a) to 2 (e) are explanatory cross-sectional drawings, showing sequential steps of surface treatment of a workpiece substrate.

FIG. 3 is a photograph showing a result of a comparison example.

### MODE FOR CARRYING OUT THE INVENTION

One embodiment of the present invention will be described hereinafter with reference to the drawings.

<Workpiece Substrate 90>

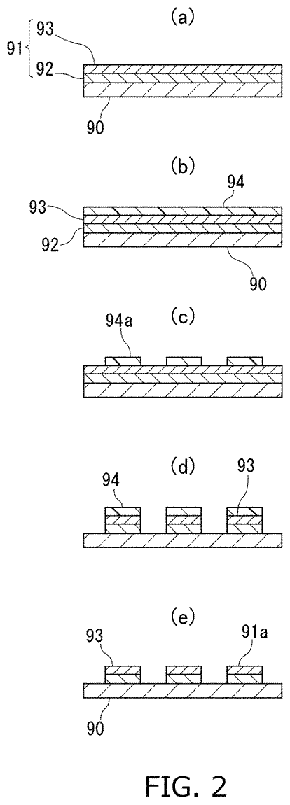

As shown in FIG. 2 (a), a workpiece substrate 90 in this embodiment is a glass substrate to be a semiconductor device such as a flat panel display, for example.

The workpiece substrate is not limited to be the glass substrate 90, but may be a silicon wafer, a resin film or the like.

A metal layer 91 to be an electrode of TFT (refer to FIG. 2 (e)), for example, is formed in the glass substrate. The metal layer 91 has a multi-layer structure including a metal base layer 92 and an easily oxidizable metal layer 93. The metal base layer 92 is made of titanium (Ti), for example. The easily oxidizable metal layer 93 is made of a metal having an easily oxidizable property, and more preferably, having a high conductivity. Preferably, the easily oxidizable metal layer 93 is made of copper (Cu).

The easily oxidizable metal layer 93 is not limited to copper (Cu), but may be made of aluminum (Al), zinc (Zn), iron (Fe) or the like. The metal layer 91 may have a single-layer structure composed of only the easily oxidizable metal layer 93 such as copper (Cu).

### <Surface Treatment Apparatus 1>

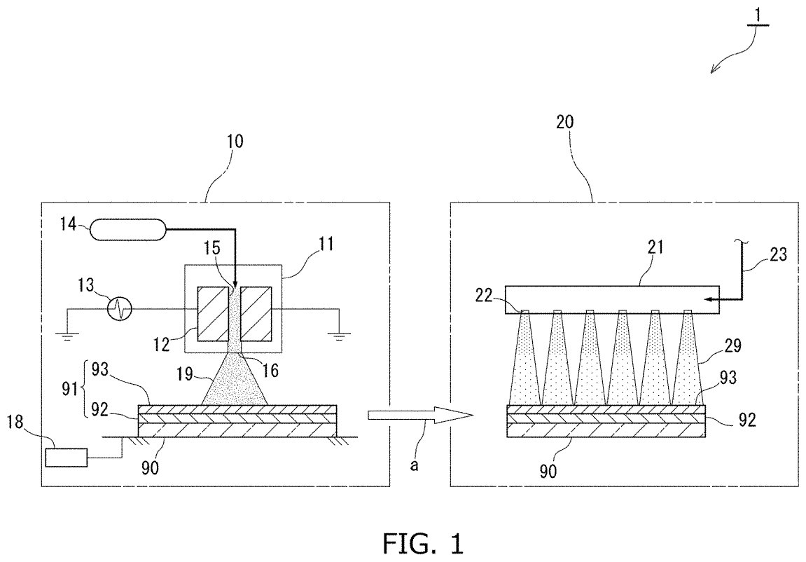

As shown in FIG. 1, a surface treatment apparatus 1 of the present embodiment includes a dry-processing part 10 and a wet-cleaning part 20.

### <Dry-Processing Part 10>

The dry-processing part 10 includes a plasma head 11 (plasma generator, activator) and a carrier 18. The plasma head 11 is provided with a pair of electrodes 12. The pair of electrodes 12 are opposed parallel to each other, thereby forming parallel plate electrodes. A space between electrodes 15 that is to be a discharge space of a near atmospheric pressure is formed between the electrodes 12. One of the electrodes is connected to a high-frequency power source 13 and the other of the electrodes is electrically grounded. At least one of the electrodes is provided with a solid dielectric layer (not shown).

An upstream end of the space between electrodes 15 continues to a process gas source 14 (reducing gaseous fluid source).

A bottom of the plasma head 11 is provided with a blowoff portion 16. A downstream end of the space between electrodes 15 continues to the blowoff portion 16.

The carrier 18 may be a roller conveyor or a movable stage.

### <Process Gas (Reducing Gaseous Fluid)>

A process gas (reducing gaseous fluid) in the process gas source 14 is a mixed gas containing a diluent gas and a reducing gas (reducing component). Nitrogen (N₂) is used as the diluent gas. The diluent gas also serves as an electric discharge generating gas. Carbon dioxide (CO), for example, is used as the reducing gas.

The process gas may further contain oxidizing gas such as CDA (clean dry air).

### <Wet-Cleaning Part 20>

As shown in FIG. 1, the wet-cleaning part 20 includes a cleaning nozzle 21. A lot of injection holes 22 are formed in the cleaning nozzle 21. A cleaning liquid supply path 23 continues from the cleaning nozzle 21. Water is used as a cleaning liquid 29.

A surface of the workpiece substrate 90 is treated in the following manner.

### <Activating Step>

As shown in FIG. 1, the process gas is introduced to the space between electrodes 15 of the plasma head 11 from the process gas source 14. And high-frequency power having a pulse waveform, for example, is supplied from the power source 13 to the electrodes 12. Thereby, glow discharge of a near atmospheric pressure is formed in the space between electrodes 15, and the space between electrodes 15 becomes a discharge space. The process gas is turned into plasma (activated) in the discharge space 15.

The process gas turned into plasma is referred to as a plasma gas 19 hereinafter.

The plasma gas 19 contains nitrogen-based species such as a nitrogen plasma and a nitrogen radical and reducing active species such as a carbon monoxide plasma and a carbon monoxide radical.

The plasma gas 19 may also contain a nitric acid-based oxidizing corrosive substance generated by a decomposition reaction of CDA or the like.

### <Dry-Processing Step>

The plasma gas 19 is blown off from the blowoff portion 16 and brought into contact with the workpiece substrate 90. Thereby, the surface of the workpiece substrate 90, i.e., a surface of the easily oxidizable metal layer 93 is dry-processed. Furthermore, a contact angle of the easily oxidizable metal layer 93 with water may be improved by the carbon monoxide plasma or the like.

In the dry-processing step, if an oxidizing corrosive substance is contained in the plasma gas 19, the oxidizing corrosive substance can be adhered to or adsorbed by the easily oxidizable metal layer 93. On the other hand, the reducing active species such as carbon monoxide plasma and carbon monoxide radical may also be contacted with the easily oxidizable metal layer 93. When the reducing active species are contacted with the oxidizing corrosive substance, a reaction to reduce the oxidizing corrosive substance occurs. Therefore, even if the oxidizing corrosive substance is adhered to or adsorbed by the easily oxidizable metal layer 93, the oxidizing corrosive substance can be reduced and removed.

An entire surface of the workpiece substrate 90 is dry-processed by concurrently transporting the workpiece substrate 90 by the carrier 18.

Alternatively, a position of the workpiece substrate 90 may be fixed and the plasma head 11 may be moved.

### <Transferring Step>

Subsequently, as indicated in FIG. 1 by the hollow arrow a, the dry-processed workpiece substrate 90 is transferred to the wet-cleaning part 20.

Fine misty water from the wet-cleaning part 20 may float in the atmosphere near the wet-cleaning part 20. In this case, the misty water may adhere to the surface of the easily oxidizable metal layer 93 during the transferring of the workpiece substrate 90.

On the other hand, as mentioned above, even if the oxidizing corrosive substance is contained in the plasma gas 19 in the dry-processing step, the water adhered to the easily oxidizable metal layer 93 can be prevented from becoming a corrosive aqueous solution by reducing the oxidizing corrosive substance. Therefore, the copper in the easily oxidizable metal layer 93 will not be resolved in the corrosive aqueous solution. As a result, the easily oxidizable metal layer 93 can be prevented or suppressed from having scattered or spotted damages formed therein.

### <Wet-Cleaning Step>

As shown in FIG. 1, the water 29 (cleaning liquid) is jetted out of the injection holes 22 in the wet-cleaning part 20. Thereby, the workpiece substrate 90 can be washed with water.

Even if the oxidizing corrosive substance remains in the easily oxidizable metal layer 93 when the workpiece substrate 90 is introduced to the wet-cleaning part 20, a concentration of the generated corrosive aqueous solution is very low since an amount of the cleaning water 29 is sufficiently greater than an amount of the oxidizing corrosive substance. Therefore, elution of the copper from the easily oxidizable metal layer 93 hardly occurs.

### <Formation of Electrode Pattern>

After that, as shown in FIG. 2 (b), a resist 94 is laminated on the easily oxidizable metal layer 93. The contact angle of the workpiece substrate 90 is reduced and the hydrophilic property of the workpiece substrate 90 is enhanced by the dry-processing step and the wet-processing step, thereby adhesion with the resist 94 can be improved.

Subsequently, as shown in FIG. 2 (c), a resist pattern 94a is formed by exposing and developing the resist 94.

Subsequently, as shown in FIG. 2 (d), an electrode pattern 91a is formed by etching according to the resist pattern 94a.

Subsequently, as shown in FIG. 2 (e), the resist 94 is removed.

Since the easily oxidizable metal layer 93 is not damaged in the cleaning step, a good electrode pattern can be formed, and a wiring failure can be suppressed or prevented.

Yield can be enhanced by performing dry-processing with atmospheric pressure plasma.

The present invention is not limited to the embodiment described above. Various modifications can be made without departing from the scope and spirit of the invention.

For example, the process gas does not necessarily contain oxidizing gas such as oxygen (O₂).

The diluent gas in the process gas is not limited to the nitrogen. Instead, diluent gas such as helium (He), argon (Ar) or neon (Ne) may be used.

The reducing gas is not limited to carbon monoxide (CO). Instead, hydrogen (H₂), hydrogen sulfide (H₂S), hydrogen peroxide (H₂O₂) or hydrogen-oxygen-containing compounds (lower alcohol such as methanol and ethanol, water or the like) may be used.

The process gas may be generated by bubbling and vaporizing the reducing solvent (liquid) in a carrier gas such as N₂.

The reducing gaseous fluid may be a mixture of lower alcohol such as ethanol and water, for example. The reducing gaseous fluid such as the mixed fluid is turned into a state of gas or mist, brought into contact with the workpiece substrate 90, and adhered to or adsorbed on the surface of the workpiece substrate 90. Preferably, the reducing gaseous fluid in the state of gas is contacted with the workpiece substrate 90 and condensed on the workpiece substrate 90. Thereby, the reducing gaseous fluid is fixed on the workpiece substrate 90. Subsequently, the oxidizing gas containing nitrogen and oxygen, for example, may be activated by plasma or UV irradiation and brought into contact with the workpiece substrate 90 on which the reducing gaseous fluid is fixed. Thereby, on the surface of the workpiece substrate 90, a cleaning reaction by the activated oxidizing gas occurs, and a reaction to reduce the oxidizing gas by the reducing gaseous fluid also occurs. As a result, the metal layer can be surely prevented from corrosion and the cleaning effect can be enhanced.

The electrode structure of the plasma head 11 can be modified as appropriate.

The pair of parallel plate electrodes may be opposed to each other in a vertical direction. The electrode on the lower side (preferably earthed electrode) may have one or plurality of blowoff openings formed therein and the plasma gas may be blown off downwards from the blowoff openings.

Alternatively, the pair of electrodes may be composed of a columnar electrode having a horizontal axis and a concave cylindrical surface electrode surrounding the columnar electrode. A lower end portion of the concave cylindrical surface electrode in a circumferential direction may be open and the plasma gas may be blown off downwards from the opening.

The activator is not limited to the plasma generator, but may be a corona discharger, an ultraviolet irradiator or a microwave irradiator.

### Example 1

Examples are described hereinafter. The present invention is not limited to the examples given below.

Dry-processing and wet-cleaning were performed using an apparatus having substantially same features as the apparatus 1 shown in FIG. 1.

A glass substrate having dimensions given below was used as a workpiece substrate 90.

Width (dimension in a direction orthogonal to the plane of FIG. 1): 50 mm

Length (dimension in a left-right direction in FIG. 1): 50 mm

Thickness: 0.7 mm

The oxidizable metal layer 93 was made of Cu.

A contact angle of a surface of the workpiece substrate 90, and further a surface of the easily oxidizable metal layer 93 with water before cleaning was 110 degrees.

Plasma irradiation conditions in a dry-processing part 10 are as follows:

Supply power: 0.8 kW

Frequency: 40 Hz

Width between electrodes 12 (dimension in a direction orthogonal to the plane of FIG. 1): 19 mm

Gap between the electrodes: 1 mm

Distance from a blowoff portion 16 to the substrate 90 (working distance):

3 mm

The workpiece substrate 90 was relatively moved (scanned) with respect to a plasma head 11. The number of times of processing (number of times of one-way movement) was one.

Six different compositions of a process gas as shown in Table 1 ((1) to (6)) were used. Carbon monoxide (CO), hydrogen peroxide (H₂O₂) and methanol (CH₃OH) were used as a reducing gas ((1) to (4)). In (4), methanol (CH₃OH) was added to nitrogen (N₂) by bubbling.

A cleaning liquid 29 in a wet-cleaning part 20 was water.

### <Evaluation>

The workpiece substrate after the dry-processing and the wet-cleaning was visually observed to check damages to the easily oxidizable metal layer on the surface of the substrate.

As shown in Table 1, it was confirmed that the easily oxidizable metal layer can be suppressed or prevented from being damaged by making the process gas contain the reducing gas.

Table 1 shows the contact angles of the surface of the substrate after the dry-processing and the wet-cleaning. After the cleaning, hydrophilic property was enhanced and adhesion of a resist 94 was improved.

### Comparison Example

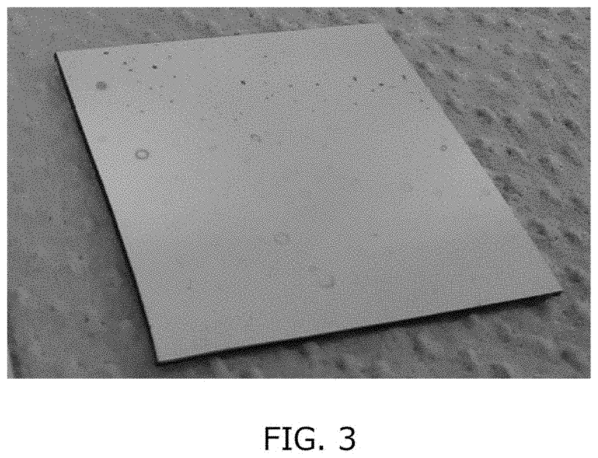

As shown in the photograph of FIG. 3, in a case where a process gas does not contain a reducing gas ((5) Comparison Example in Table 1), scattered or spotted traces of dissolution (damages) were formed on an easily oxidizable metal layer on a surface of a substrate.

TABLE 1

| | | | | | | | | | | (5) Comparison | |
|---|---|---|---|---|---|---|---|---|---|---|---|
| | | (1) | | (2) | | (3) | | (4) | | Example | |
| Process Gas | N₂ | 100 | slm | 160 | slm | 100 | slm | 100 | slm | 100 | slm |
| | CO | 100 | sccm | 250 | sccm | 0 | slm | 0 | slm | 0 | slm |
| | CDA | 0 | sccm | 0 | sccm | 0 | sccm | 0 | sccm | 250 | sccm |
| | H₂O₂ | 0 | sccm | 0 | sccm | 100 | sccm | 0 | sccm | 0 | sccm |

| | | | | | | | | | |
|---|---|---|---|---|---|---|---|---|---|
| CH₃OH | 0 | sccm | 0 | sccm | 0 | sccm | Bubbling | 0 | sccm |

| | | | | | | |
|---|---|---|---|---|---|---|
| Evaluation | Damage | Not Found | Not Found | Not Found | Not Found | Found |
| | Contact Angle | 52.2° | 42.3° | 42.6° | 48.3° | 43.5° |
| | after Cleaning | | | | | |

### INDUSTRIAL APPLICABILITY

The present invention may be applied to manufacturing of a flat panel display, for example.

### EXPLANATION OF REFERENCE NUMERALS

1 surface treatment apparatus
10 dry-processing part
11 plasma head (plasma generator, activator)
12 electrode
13 power source
14 process gas source (reducing gaseous fluid source)
15 space between electrodes (discharge space)
16 blowoff portion
18 carrier
19 plasma gas (activated reducing gaseous fluid)
20 wet-cleaning part
21 cleaning nozzle
22 injection hole
23 cleaning liquid supply path
29 water (cleaning liquid)
90 glass substrate (workpiece substrate)
91 metal layer
91a electrode pattern
92 metal base layer
93 easily oxidizable metal layer
94 photoresist
94a resist pattern

1. A surface treatment method for treating a surface of a workpiece substrate including an easily oxidizable metal layer, the method comprising steps of:
bringing a reducing gaseous fluid containing a reducing component into contact with the workpiece substrate;
activating the reducing gaseous fluid generally concurrently with the contacting; and subsequently
cleaning the workpiece substrate with cleaning liquid.

2. The surface treatment method according to claim 1, wherein the reducing component contains at least one selected from a group of hydrogen (H₂), hydrogen sulfide (H₂S), hydrogen peroxide (H₂O₂), carbon monoxide (CO) and a hydrogen-oxygen-containing compound.

3. The surface treatment method according to claim 1, wherein the activation is performed by plasma treatment, corona discharge treatment, ultraviolet irradiation treatment or microwave irradiation treatment.

4. The surface treatment method according to claim 1, wherein the activation is performed by generating electric discharge between a pair of electrodes.

5. The surface treatment method according to claim 1, wherein the reducing gaseous fluid is fixable to the workpiece substrate by the contacting with the workpiece substrate; and
oxidizing gaseous fluid is activated and brought into contact with the workpiece substrate on which the reducing gaseous fluid is fixed.

6. The surface treatment method according to claim 1, wherein the easily oxidizable metal layer contains at least one kind of metal selected from a group of copper, aluminum, iron and zinc.

7. A surface treatment apparatus for treating a surface of a workpiece substrate including an easily oxidizable metal layer, the apparatus comprising:
a dry-processing part, wherein a reducing gaseous fluid containing a reducing component is brought into contact with the workpiece substrate and the reducing gaseous fluid is activated generally concurrently with the contacting; and
a wet-cleaning part, wherein the workpiece substrate after the contacting is cleaned with cleaning liquid.

8. The surface treatment apparatus according to claim 7, wherein the dry-processing part comprises a pair of electrodes and the activation is performed by generating electric discharge between the electrodes.
